(19) United States
(12) Patent Application Publication
(10) Pub. No.: US 2002/0045336 A1
(43) Pub. Date: Apr. 18, 2002

(54) METHODS FOR FORMING IMPROVED PASSIVATION LAYERS FOR INTEGRATED CIRCUITS

(76) Inventors: VANDA LOCATI, BERGAMO (IT); GINO CLEMENTE, BERNAREGGIO (IT)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 09/215,648

(22) Filed: Dec. 17, 1998

(30) Foreign Application Priority Data
Dec. 18, 1997 (EP) 97830685.0

(51) Int. Cl. H01L 21/4763; H01L 21/31; H01L 21/469

(52) U.S. Cl. 438/627; 438/637; 438/643; 438/787

(57) ABSTRACT

Process for passivating an integrated circuit, providing for the formation on a top surface of the integrated circuit of at least a first layer of undoped oxide, characterized in that said first layer of undoped oxide is formed by means of a chemical vapor deposition process performed at a pressure suitable for causing said first undoped oxide layer to substantially completely fill hollow regions between projecting regions of the top surface of the integrated circuit.

### TECHNICAL FIELD

The invention relates generally to integrated circuits, and more particularly to a method for forming a passivation layer on an integrated circuit.

### BACKGROUND OF THE INVENTION

Conventional integrated circuits typically use passivation layers to protect them from mechanical stresses, oxidation, contamination and to achieve planarization. In particular, the passivation layer provides a hermetic seal around the vertical walls of the strips formed in the uppermost metal level. This property becomes increasingly difficult to achieve as the feature size of integrated circuits shrinks, and the difficulty is exacerbated as the aspect ratio of component features grows, e.g., the exposed area of the vertical walls of the metal strips is significantly larger than the exposed area of the top of the strips.

One known passivation method is disclosed in EP-A-0655776. This method provides for forming over a top surface of an integrated circuit to be protected a layer of undoped silicon dioxide (Undoped Silicon Glass or USG) layer, then a layer of phosphorus-doped silicon dioxide (Phosphorus doped Silicon Glass or PSG) and then a layer of silicon oxidonitride (SixOyNz).

Normally the passivation layer is formed by deposition over the whole surface of the integrated circuit. Subsequently, the passivation layer is selectively removed from over contact or bonding pad areas (areas wherein conductive wires are to be soldered to enlarged metallized regions) by means of conventional photolithographic techniques (deposition of photoresist material, exposure to light, selective removal of the photoresist, etching of the uncovered areas of the passivation layer, complete removal of the remaining photoresist).

The above-mentioned passivation method providing for the formation of a triple layer of undoped oxide, doped oxide and oxidonitride, as well as other conventional passivation methods, do not guarantee that the passivation layer will completely fill the gaps between features, such as the metal strips. The integrated circuit having a passivation layer formed by conventional methods is therefore subject to potential problems, such as formation of cracks, popping of the photoresist, presence of residual photoresist within the gaps between the metal strips, etc.

### SUMMARY OF THE INVENTION

In view of the state of the art described, it is an object of the present invention to provide a process for the final passivation of integrated circuits resolving the problems connected to the use of the known passivation processes in a context of continuous reduction of the geometries of the integrated circuits.

According to the present invention such an object is achieved by means of a process for the final passivation of an integrated circuit, providing for the formation on a top surface of the integrated circuit of at least a first layer of undoped oxide, characterized in that said first layer of undoped oxide is formed by means of a chemical vapor deposition process performed at a pressure suitable for causing said first undoped oxide layer to substantially completely fill hollow regions between projecting regions of the top surface of the integrated circuit.

### BRIEF DESCRIPTION OF THE DRAWINGS

FIGS. 1 to 4 are cross-sectional views of a portion of an integrated circuit to be passivated, taken at intermediate steps of a process of final passivation according to an embodiment of the present invention.

### DETAILED DESCRIPTION OF THE INVENTION

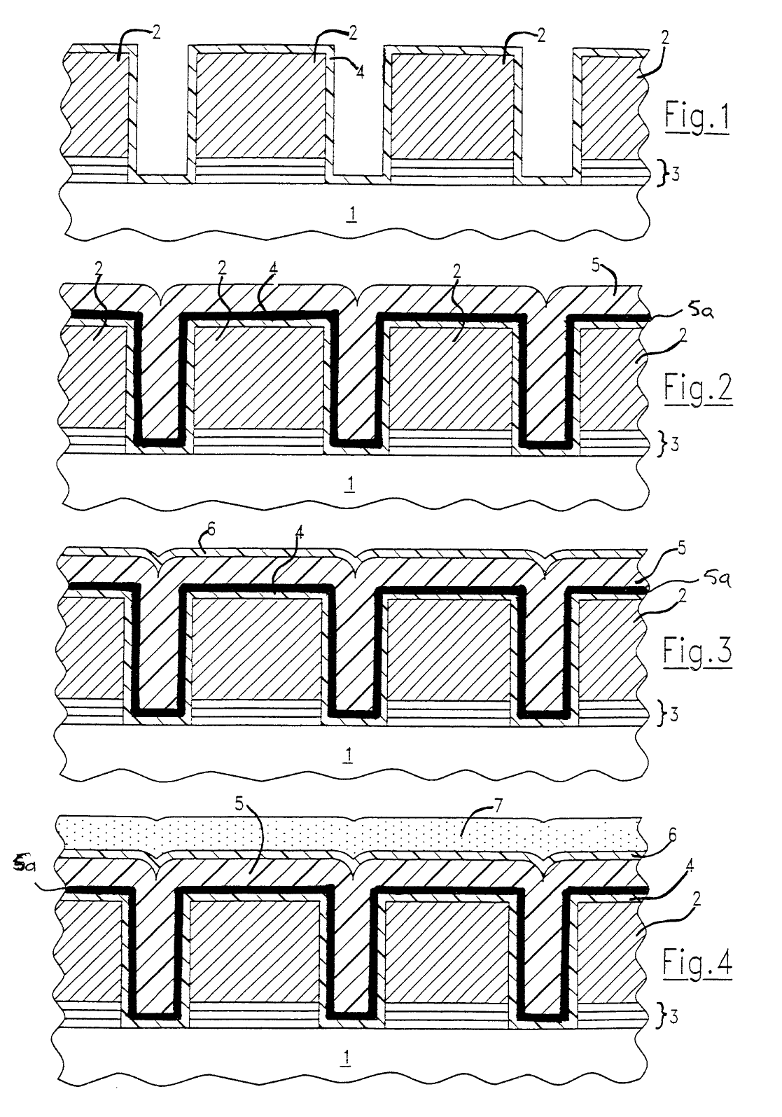

FIG. 1 is a portion of an integrated circuit to be passivated is shown. The integrated circuit generically comprises a semiconductor material substrate 1 over which a pattern of, e.g., metal strips 2 is formed, the metal strips 2 being for example formed over a stack 3 of other layers of different materials. This is not essential to the present invention; the only thing to be noted is that generally the surface of the integrated circuit to be passivated is rough, with projecting regions and hollow regions.

In its preferred embodiment, the process of final passivation of the present invention provides for the formation over the top surface of the integrated circuit to be passivated of a first layer 4 of undoped silicon dioxide, which acts as a barrier layer. As shown in FIG. 1, this layer 4 follows the profile of the integrated circuit surface, but does not fill the hollow regions between the metal strips 2. The formation of this layer 4 can be achieved by means of conventional Chemical Vapor Deposition (CVD).

Subsequently (FIG. 2), a second layer of undoped silicon dioxide 5 is formed. This layer is also formed by means of CVD, as layer 4. However, while layer 4 is formed by means of a substantially conventional CVD process, the deposition for the formation of layer 5 is performed at a pressure in a range suitable for the layer 5 to have a good filling factor. It has in fact been verified that, as far as the capability of filling hollow regions is concerned, the pressure is the most important process parameter in a process of formation of an oxide layer by means of CVD. Suitable pressure values range of 350 to 600 Torr, which make the deposition process a Sub-Atmospheric pressure CVD (SACVD).

In one embodiment, the step of deposition of the filling oxide layer 5 is preceded by a step of deposition of a glue layer 5a performed in the same reaction chamber with the same chemical reactants as the step of deposition of the filling oxide layer 5, but at a much lower pressure of, e.g., 40 to 60 Torr.

As schematically shown in FIG. 2, layer 5 completely fills the gaps between the metal strips 2.

Then, a third layer of undoped silicon dioxide 6 is formed, again by means of conventional CVD, over the filling layer 5 to encapsulate the underlying layers (FIG. 3). The process conditions for the deposition of layer 6 can be identical to those used for depositing the barrier layer 4.

The thickness of the three undoped oxide layers 4, 5 and 6, and in particular the thickness of the filling oxide layer 5, depends on the desired filling factor as well as on the smallest gaps to be filled. However, it is also to be taken into consideration that an important limiting factor for the layer's thickness is related to the stresses of the underlying and overlying layers.

The passivation process can be completed with the formation of layers (schematically indicated with 7 in FIG. 4) of material conventionally employed in standard final passivation processes. For example, over layer 6 a layer of doped silicon dioxide can be formed, as well as a layer of silicon oxidonitride. In the case of integrated circuits including UV erasable memory cells, oxidonitride shall not be used, because it blocks UV rays.

The present description has been directed to a preferred embodiment of the invention, providing for the deposition of three layers 4, 5 and 6 of undoped silicon dioxide. However, it should be noted that the present invention could as well provide for the formation of only one layer, namely the filling layer 5, which can be considered the essential feature of the invention. It is the filling layer 5 that fills the gaps between the metal strips 2, preventing that other materials, such as, e.g., the photoresist used for the selective etching of the passivation layer over the bonding pads, penetrates in the hollow regions.

However, the three layers of undoped oxide 4, 5 and 6 can be advantageously formed in sequence, varying the process condition (in particular, the pressure) inside the reaction chamber used for the chemical vapor deposition.

The passivation process according to the present invention is advantageous in that it is compatible with the already existing passivation processes, and it can easily implemented. Additionally, the process of the invention provides a good degree of filling even in presence of structures having high aspect ratios, and at the same time provides a good degree of planarization.

1. Process for passivating an integrated circuit, providing for the formation on a top surface of the integrated circuit of at least a first layer of undoped oxide, characterized in that said first layer of undoped oxide is formed by means of a chemical vapor deposition process performed at a pressure suitable for causing said first undoped oxide layer to substantially completely fill hollow regions between projecting regions of the top surface of the integrated circuit.

2. Process according to claim 1, characterized in that said chemical vapor deposition process is a Sub-Atmospheric pressure Chemical Vapor Deposition process.

3. Process according to claim 2, characterized in that said pressure is in the range 350 to 600 Torr.

4. Process according to claim 3, characterized by providing for the formation, prior to said first undoped oxide layer, of a second undoped oxide layer following the profile of the top surface of the integrated circuit and acting as a barrier layer.

5. Process according to claim 4, characterized by providing for the formation, over said first undoped oxide layer, of a third undoped oxide layer encapsulating the first undoped oxide layer.

6. Process according to claim 5, characterized in that said second, first and third undoped oxide layers are formed in sequence by means of a same chemical vapor deposition process varying the process conditions.

7. Process according to claim 5, characterized by providing for forming, over the third undoped oxide layer, of a doped oxide layer.

8. Process according to claim 7, characterized by providing for forming, over the layer of doped oxide, of a layer of oxidonitride.

9. A method for uniformly filling a recessed region within a surface of a semiconductor wafer, comprising:
depositing a filling layer of a silicon oxide in the recessed region by low pressure chemical vapor deposition, the pressure being approximately 350-600 Torr, the filling layer substantially and uniformly filling the recessed region.

10. The method of claim 9 wherein the silicon oxide comprises at least one of silicon dioxide and undoped silicon dioxide.

11. The method of claim 9, further comprising:
forming a barrier layer of a silicon oxide disposed between the filling layer and the surface of the semiconductor wafer.

12. The method of claim 11 wherein the barrier layer is formed by chemical vapor deposition.

13. The method of claim 11 wherein the silicon oxide comprises undoped silicon dioxide.

14. A method for forming a passivation layer on a surface of a semiconductor wafer, the surface having a recessed region, comprising:
forming a barrier layer of undoped silicon dioxide on the semiconductor wafer, the barrier layer being formed by chemical vapor deposition (CVD); and
depositing a passivation layer of undoped silicon dioxide over the barrier layer by CVD, the deposition of the passivation layer being performed at a pressure between approximately 350 and 600 Torr, the passivation layer substantially filling the recessed region.

15. The method of claim 14 wherein the passivation layer completely and uniformly fills the recessed regions.

16. The method of claim 14 wherein the passivation layer forms a layer of material disposed on the integrated circuit having a substantially planar boundary.

17. The method of claim 14, further comprising:
depositing a glue layer of silicon dioxide disposed between the barrier layer and the passivation layer, the deposition of the glue layer of silicon dioxide being performed by CVD at a pressure between approximately 40 and 60 Torr.

18. The method of claim 14, further comprising:
depositing an encapsulating layer of silicon dioxide over the passivation layer by CVD.

19. The method of claim 18, further comprising:
depositing a layer of doped silicon dioxide over the encapsulating layer.

20. The method of claim 14, further comprising:
depositing a layer of silicon oxidonitride over the layer of doped silicon.
